(19) United States
(12) Patent Application Publication
(10) Pub. No.: US 2024/0324477 A1
(43) Pub. Date: Sep. 26, 2024

(54) STORAGE DEVICE AND METHOD OF MANUFACTURING A STORAGE DEVICE

(71) Applicant: Kioxia Corporation, Tokyo (JP)

(72) Inventors: Soichiro ONO, Seongnam-si Gyeonggi-do (KR); Hiroyuki KANAYA, Yokohama Kanagawa (JP)

(21) Appl. No.: 18/593,589

(22) Filed: Mar. 1, 2024

(30) Foreign Application Priority Data
Mar. 22, 2023 (JP) 2023-045402

(51) Int. Cl. H10N 70/00; H10B 63/00

(52) U.S. Cl. CPC H10N 70/841; H10B 63/84; H10N 70/011; H10N 70/8828

(57) ABSTRACT

A storage device includes a memory cell that includes a variable resistance storage element and a switching element connected in series thereto and stacked therewith in a first direction, the switching element including a first electrode, a second electrode that includes a first part formed of a first material to which a first element is added, and a switching material layer that is between the first electrode and the first part of the second electrode and formed of a first insulating material to which the first element is added. The storage device further includes a first insulating layer that surrounds the switching material layer and formed of the first insulating material to which the first element is not added. An outer periphery of the first part of the second electrode and an outer periphery of the switching material layer are aligned in the first direction.

### CROSS-REFERENCE TO RELATED APPLICATION(S)

This application is based upon and claims the benefit of priority from Japanese Patent Application No. 2023-045402, filed Mar. 22, 2023, the entire contents of which are incorporated herein by reference.

### FIELD

Embodiments described herein relate generally to a storage device and a method of manufacturing a storage device.

### BACKGROUND

A storage device in which memory cells including a variable resistance storage element such as a magnetoresistive effect element and a switching element are integrated on a semiconductor substrate, is known.

### DESCRIPTION OF THE DRAWINGS

FIG. 1 is a perspective view schematically illustrating a schematic basic configuration of a storage device according to a first embodiment.

FIG. 2 is a plan view schematically illustrating a configuration of the storage device according to the first embodiment.

FIGS. 3A and 3B are cross-sectional views schematically illustrating the configuration of the storage device according to the first embodiment.

FIG. 4 is a cross-sectional view schematically illustrating a configuration of a magnetoresistive effect element of the storage device according to the first embodiment.

FIG. 5 is a diagram schematically illustrating a current-voltage characteristic of a selector of the storage device according to the first embodiment.

FIGS. 6A and 6B to FIGS. 19A and 19B are cross-sectional views schematically illustrating a part of a method of manufacturing the storage device according to the first embodiment.

FIG. 20 is a perspective view schematically illustrating a schematic basic configuration of a storage device according to a second embodiment.

FIG. 21 is a plan view schematically illustrating a configuration of the storage device according to the second embodiment.

FIGS. 22A and 22B are cross-sectional views schematically illustrating the configuration of the storage device according to the second embodiment.

FIGS. 23A and 23B to FIGS. 25A and 25B are cross-sectional views schematically illustrating steps of the method of manufacturing the storage device according to the second embodiment.

FIG. 26 is a plan view schematically illustrating a configuration of a storage device according to a third embodiment.

FIG. 27 is a cross-sectional view schematically illustrating the configuration of the storage device according to the third embodiment.

FIG. 28 is a cross-sectional view schematically illustrating a configuration of a storage device according to a first modification example of the third embodiment.

FIG. 29 is a cross-sectional view schematically illustrating a configuration of a storage device according to a second modification example of the third embodiment.

FIG. 30 is a plan view schematically illustrating a configuration of a storage device according to a fourth embodiment.

FIG. 31 is a cross-sectional view schematically illustrating the configuration of the storage device according to the fourth embodiment.

FIGS. 32-34 are cross-sectional views schematically illustrating steps of the method of manufacturing the storage device according to the fourth embodiment.

FIG. 35 is a cross-sectional view schematically illustrating a configuration of a storage device according to a first modification example of the fourth embodiment.

FIG. 36 is a cross-sectional view schematically illustrating a configuration of a storage device according to a second modification example of the fourth embodiment.

### DETAILED DESCRIPTION

Embodiments provide a storage device having excellent characteristics.

In general, according to one embodiment, a storage device includes a memory cell that includes a variable resistance storage element and a switching element connected in series to the variable resistance storage element and stacked with the variable resistance storage element in a first direction, the switching element including a first electrode, a second electrode that includes a first part formed of a first material to which a first element is added, and a switching material layer that is provided between the first electrode and the first part of the second electrode and that is formed of a first insulating material to which the first element is added, and a first insulating layer that surrounds the switching material layer and is formed of the first insulating material to which the first element is not added. An outer periphery of the first part of the second electrode and an outer periphery of the switching material layer are aligned in the first direction.

Hereinafter, embodiments will be described with reference to the drawings.

### First Embodiment

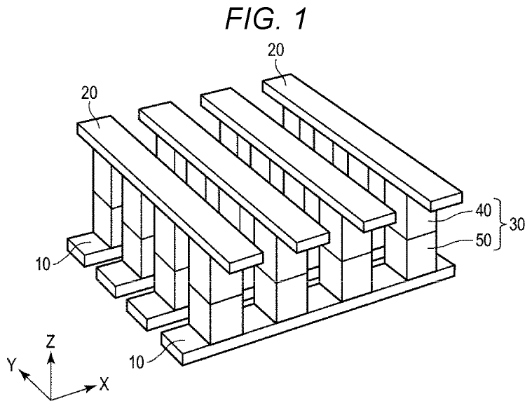

FIG. 1 is a perspective view schematically illustrating a schematic basic configuration of a storage device, which is non-volatile, according to a first embodiment.

The structure illustrated in FIG. 1 is provided on a lower structure (not illustrated) including a semiconductor substrate (not illustrated) and includes a plurality of wires 10 each extending in an X direction, a plurality of wires 20 each extending in a Y direction, and a plurality of memory cells 30 provided between the plurality of wires 10 and the plurality of wires 20. One of the wire 10 and the wire 20 corresponds to a word line, and the other of the wire 10 and the wire 20 corresponds to a bit line.

The memory cell 30 includes a magnetoresistive effect element (which is a variable resistance storage element) 40 and a selector (which is a switching element) 50 connected in series to the magnetoresistive effect element 40 and has a structure in which the magnetoresistive effect element 40 and the selector 50 are stacked in a Z direction. In the present embodiment, the magnetoresistive effect element 40 is provided on an upper layer side of the selector 50.

The X direction, the Y direction, and the Z direction are directions intersecting with each other. Specifically, the X direction, the Y direction, and the Z direction are orthogonal to each other.

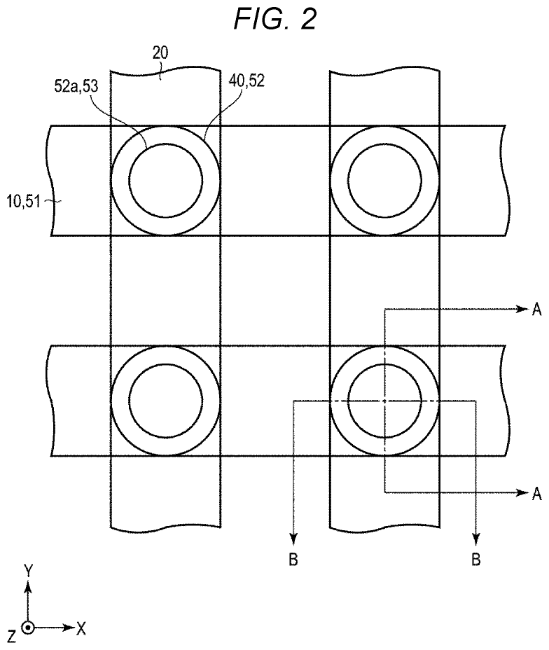

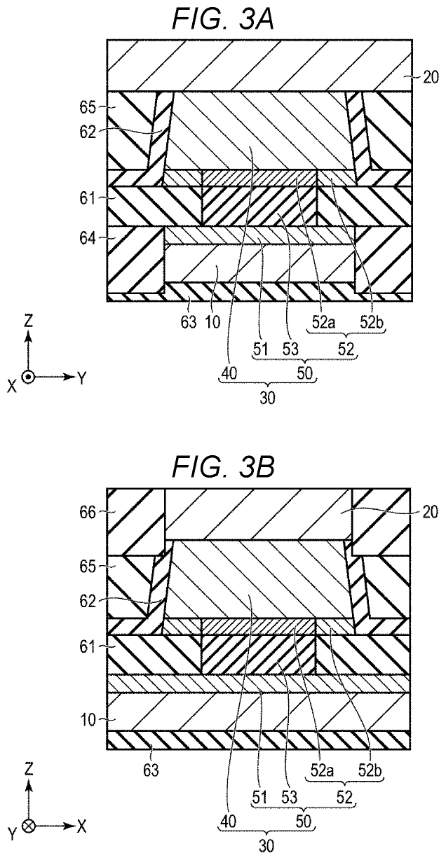

FIG. 2 is a plan view schematically illustrating a configuration of the storage device according to the present embodiment. FIGS. 3A and 3B are cross-sectional views schematically illustrating the configuration of the storage device according to the present embodiment. A cross section taken along line A-A in FIG. 2 corresponds to FIG. 3A, and a cross section taken along line B-B in FIG. 2 corresponds to FIG. 3B.

As illustrated in FIGS. 2, 3A, and 3B, the storage device includes the wire 10, the wire 20, the memory cell 30 including the magnetoresistive effect element 40 and the selector 50, and insulating layers 61 to 66.

As described previously, the wire 10 extends in the X direction, and the wire 20 extends in the Y direction. One of the wire 10 and the wire 20 correspond to the word line, and the other of the wire 10 and the wire 20 correspond to the bit line.

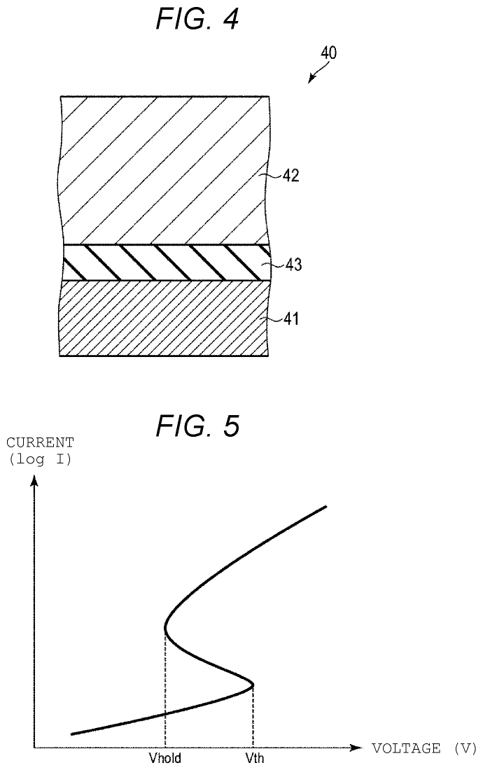

FIG. 4 is a cross-sectional view schematically illustrating a configuration of the magnetoresistive effect element 40.

The magnetoresistive effect element 40 is a magnetic tunnel junction (MTJ) element and includes a storage layer (which is a magnetic layer) 41, a reference layer (which is also a magnetic layer) 42, and a tunnel barrier layer (which is a non-magnetic layer) 43.

The storage layer 41 is a ferromagnetic layer having a variable magnetization direction. The reference layer 42 is a ferromagnetic layer having a fixed magnetization direction. The variable magnetization direction means that the magnetization direction changes in response to a predetermined current flowing therethrough. The fixed magnetization direction means that the magnetization direction does not change in response to the predetermined current flowing therethrough. The tunnel barrier layer 43 is an insulating layer provided between the storage layer 41 and the reference layer 42.

When the magnetization direction of the storage layer 41 is parallel to the magnetization direction of the reference layer 42, the magnetoresistive effect element 40 enters a low resistance state in which resistance is relatively low. When the magnetization direction of the storage layer 41 is antiparallel to the magnetization direction of the reference layer 42, the magnetoresistive effect element 40 enters a high resistance state in which resistance is relatively high. Accordingly, the magnetoresistive effect element 40 can store binary data in accordance with the resistance state of the magnetoresistive effect element 40.

The magnetoresistive effect element 40 is a spin transfer torque (STT) magnetoresistive effect element having perpendicular magnetization. The magnetization direction of the storage layer 41 is perpendicular to a principal surface of the storage layer 41, and the magnetization direction of the reference layer 42 is perpendicular to a principal surface of the reference layer 42.

Returning back to description of FIGS. 2, 3A, and 3B, the selector 50 is a two-terminal switching element and includes a lower electrode 51, an upper electrode 52, and a selector material layer (also referred to as a switching material layer) 53.

The lower electrode 51 is formed of a predetermined conductive material and is connected to the wire 10. In the present embodiment, a layout of the lower electrode 51 follows a layout of the wire 10 when viewed from the Z direction. That is, when viewed from the Z direction, the layout of the lower electrode 51 coincides with the layout of the wire 10, and the layout of the lower electrode 51 is substantially the same as the layout of the wire 10.

The upper electrode 52 has a first part 52a and a second part 52b. The first part 52a and the second part 52b are contiguously provided and have the same thickness. The upper electrode 52 also functions as a lower electrode of the magnetoresistive effect element 40, and a shape of the upper electrode 52 corresponds to a shape of the magnetoresistive effect element 40 when viewed from the Z direction. That is, when viewed from the Z direction, the shape of the upper electrode 52 coincides with the shape of the magnetoresistive effect element 40, and the shape of the upper electrode 52 is substantially the same as the shape of the magnetoresistive effect element 40.

The first part 52a is formed of a conductive material to which an additive element is added. The conductive material is selected from a titanium nitride (Ti nitride), aluminum (Al), tantalum (Ta), tungsten (W), a tungsten nitride (W nitride), copper (Cu), and carbon (C). The additive element is selected from metal elements such as arsenic (As), bismuth (Bi), tellurium (Te), and germanium (Ge).

The second part 52b surrounds the first part 52a and is positioned outside the first part 52a when viewed from the Z direction. The second part 52b is formed of the conductive material to which the additive element is not added. That is, the first part 52a and the second part 52b have the same conductive material, the additive element is added to the first part 52a, and the additive element is not added to the second part 52b.

The selector material layer 53 is provided between the lower electrode 51 and the upper electrode 52. The outer periphery of the selector material layer 53 is overlapped by the lower electrode 51 and the upper electrode 52 when viewed from the Z direction. More specifically, the selector material layer 53 is provided between the lower electrode 51 and the first part 52a of the upper electrode 52, and a shape of the first part 52a of the upper electrode 52 corresponds to the shape of the selector material layer 53 when viewed from the Z direction. That is, when viewed from the Z direction, the shape of the first part 52a of the upper electrode 52 coincides with the shape of the selector material layer 53, and the shape of the first part 52a of the upper electrode 52 substantially matches the shape of the selector material layer 53. In addition, the outer periphery of the selector material layer 53 is overlapped by the magnetoresistive effect element 40 when viewed from the Z direction.

The selector material layer 53 is formed of an insulating material to which the additive element is added. That is, the selector material layer 53 is formed of an insulating material to which the same additive element as the additive element added to the first part 52a of the upper electrode 52 is added. An oxide or a nitride is used as the insulating material of the selector material layer 53. Specifically, a silicon oxide (Si oxide), a zirconium oxide (Zr oxide), an aluminum oxide (Al oxide), a silicon nitride (Si nitride), or a hafnium oxide (Hf oxide) is used as the insulating material of the selector material layer 53.

FIG. 5 is a diagram schematically illustrating a current-voltage characteristic of the selector 50.

As illustrated in FIG. 5, the selector 50 transitions from an off state to an on state when a voltage V applied between the lower electrode 51 and the upper electrode 52 is increased and the voltage applied between the lower electrode 51 and the upper electrode 52 is increased above a threshold voltage Vth. In addition, the selector 50 transitions from the on state to the off state when the voltage V applied between the lower electrode 51 and the upper electrode 52 is decreased and the voltage applied between the lower electrode 51 and the upper electrode 52 is decreased below a hold voltage Vhold.

Accordingly, when a voltage is applied between the wire 10 and the wire 20 and the voltage applied to the selector 50 is increased above the threshold voltage Vth, the selector 50 enters the on state. Consequently, a current flows in the magnetoresistive effect element 40 connected to the selector 50, and a write operation or a read operation can be performed on the magnetoresistive effect element 40.

For example, a zero voltage is applied to the selected wire 10 connected to the selected memory cell 30, and a voltage Vsel is applied to the selected wire 20 connected to the selected memory cell 30. In addition, a voltage (Vsel/2) is applied to the non-selected wire 10 connected to the non-selected memory cell 30, and the voltage (Vsel/2) is also applied to the non-selected wire 20 connected to the non-selected memory cell 30.

The selection voltage Vsel is applied to the selected memory cell 30 by performing the above voltage application operation. In addition, the half-selection voltage (Vsel/2) is applied to the memory cell 30 connected between the selected wire 10 and the non-selected wire 20 (such memory cell referred to as half-selected memory cell). The half-selection voltage (Vsel/2) is also applied to the memory cell 30 connected between the non-selected wire 10 and the selected wire 20 (such memory cell referred to as half-selected memory cell). In addition, the zero voltage is applied to the memory cell 30 connected between the non-selected wire 10 and the non-selected wire 20 (such memory cell referred to as non-selected memory cell). The half-selected memory cell 30 is actually in a non-selected state (because the selector 50 provided in the half-selected memory cell 30 is in the off state).

As described above, the voltage Vsel is set such that the threshold voltage Vth falls between the voltage applied to the selector 50 provided in the selected memory cell 30 and the voltage applied to the selector 50 provided in the half-selected memory cell 30. By setting the voltage Vsel in this manner, only the selector 50 provided in the selected memory cell 30 can be set to enter the on state, and the write operation or the read operation can be performed on the magnetoresistive effect element 40 provided in the selected memory cell 30.

The insulating layer 61 surrounds the selector material layer 53 and is positioned outside the selector material layer 53 when viewed from the Z direction. The insulating layer 61 and the selector material layer 53 are contiguously provided and have the same thickness. The insulating layer 61 is formed of an insulating material to which the additive element is not added. That is, the selector material layer 53 and the insulating layer 61 have the same insulating material, the additive element is added to the selector material layer 53, and the additive element is not added to the insulating layer 61.

The insulating layer 62 has a function of protecting side surfaces of the magnetoresistive effect element 40 and is formed of a silicon nitride, a silicon oxide, or the like.

The insulating layers 63, 64, 65, and 66 are interlayer insulating layers and are formed of a silicon oxide or the like.

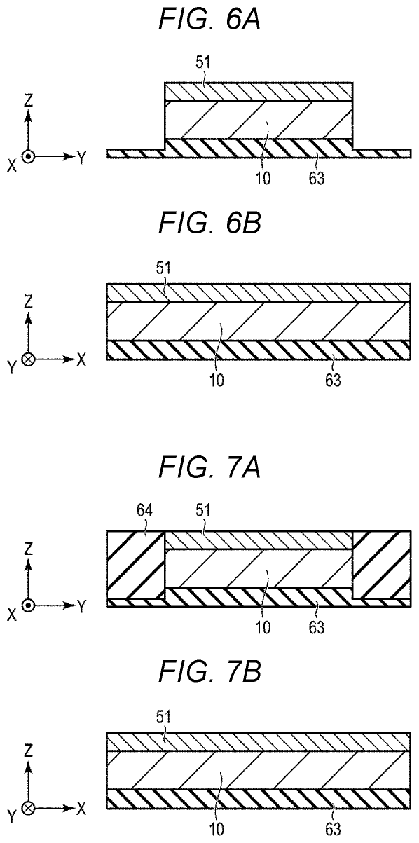

Next, a method of manufacturing the storage device according to the present embodiment will be described with reference to the cross-sectional views illustrated in FIGS. 6A and 6B to FIGS. 19A and 19B.

First, as illustrated in FIGS. 6A and 6B, a conductive layer (for example, a tungsten (W) layer) for wires is formed on the insulating layer (e.g., silicon oxide layer) 63, and a lower electrode layer is formed on the conductive layer. Next, the wire 10 extending in the X direction and the lower electrode 51 are formed by patterning the conductive layer and the lower electrode layer together to have the same planar shape.

Next, as illustrated in FIGS. 7A and 7B, the insulating layer (silicon oxide layer) 64 is formed on the structure obtained in the steps in FIGS. 6A and 6B. Next, the insulating layer 64 is flattened to expose an upper surface of the lower electrode 51.

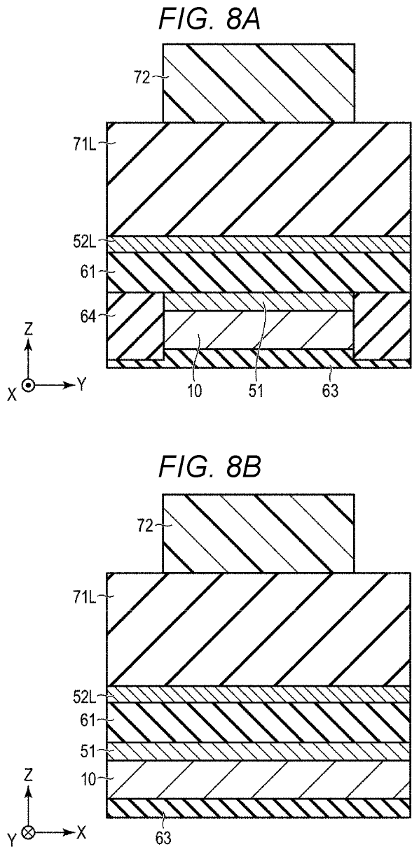

Next, as illustrated in FIGS. 8A and 8B, the insulating layer (e.g., silicon oxide layer) 61 is formed on the structure obtained in the steps in FIGS. 7A and 7B. Next, an upper electrode layer 52L is formed on the insulating layer 61, and an insulating layer (e.g., silicon oxide layer) 71L is formed on the upper electrode layer 52L. Furthermore, a patterned resist 72 is formed on the insulating layer 71L. The patterned resist 72 has a circular shape when viewed from the Z direction.

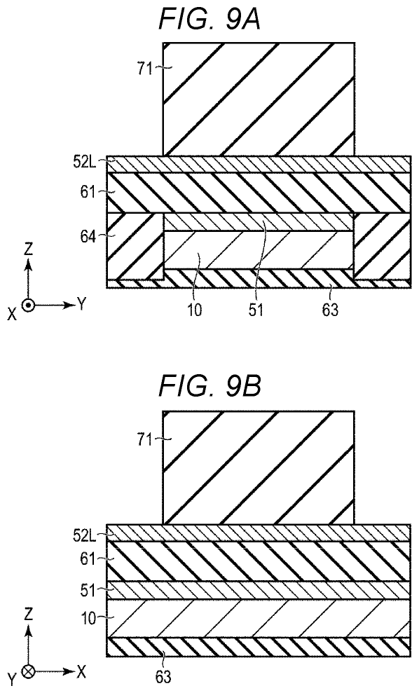

Next, as illustrated in FIGS. 9A and 9B, an insulating layer pattern 71 is formed by etching the insulating layer 71L using the patterned resist 72 formed in the steps in FIGS. 8A and 8B as a mask. Furthermore, the patterned resist 72 is removed.

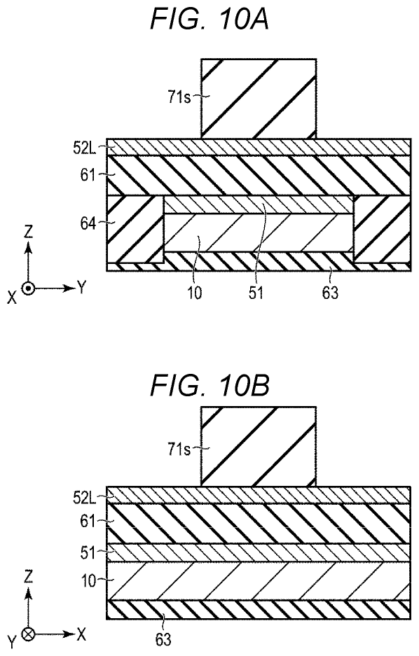

Next, as illustrated in FIGS. 10A and 10B, an insulating layer pattern 71s is formed by shrinking the insulating layer pattern 71 obtained in the steps in FIGS. 9A and 9B.

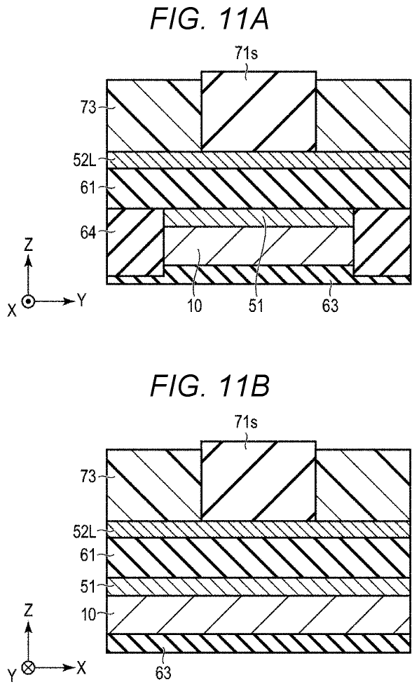

Next, as illustrated in FIGS. 11A and 11B, a resist layer is formed on the structure obtained in the steps in FIGS. 10A and 10B, and the resist layer is etched back. Accordingly, a patterned resist 73 surrounding the insulating layer pattern 71s is obtained, and an upper surface of the insulating layer pattern 71s is exposed.

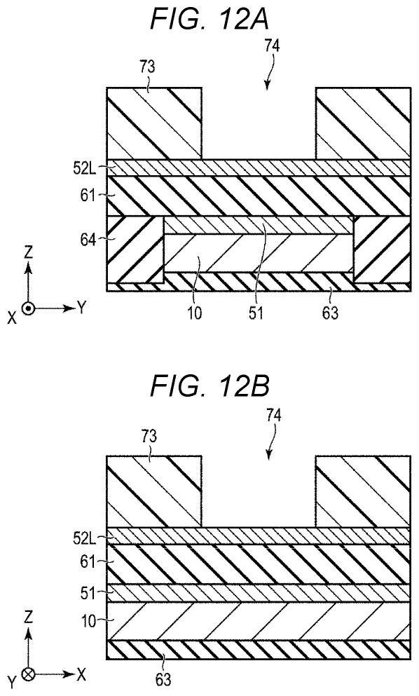

Next, as illustrated in FIGS. 12A and 12B, the patterned resist 73 having a hole pattern 74 is obtained by removing the insulating layer pattern 71s.

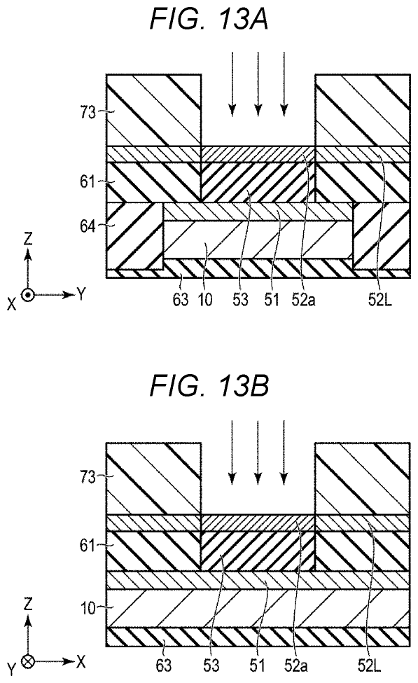

Next, as illustrated in FIGS. 13A and 13B, ions of the additive element are implanted into a part of the insulating layer 61 using the patterned resist 73 as a mask. By implanting the ions, the additive element is introduced into the part of the insulating layer 61 to form the selector material layer 53. That is, the additive element is introduced into the part of the insulating layer 61, which is formed of an insulating material to which the additive element is not added, to form the selector material layer 53. As described previously, the additive element is selected from metal elements such as arsenic, bismuth, tellurium, and germanium.

In the ion implantation step, the ions of the additive element are implanted into the part of the insulating layer 61 through the upper electrode layer 52L. Thus, by implanting the ions, the additive element is also introduced into a part of the upper electrode layer 52L to form the first part 52a of the upper electrode 52 (which is formed in a step described later).

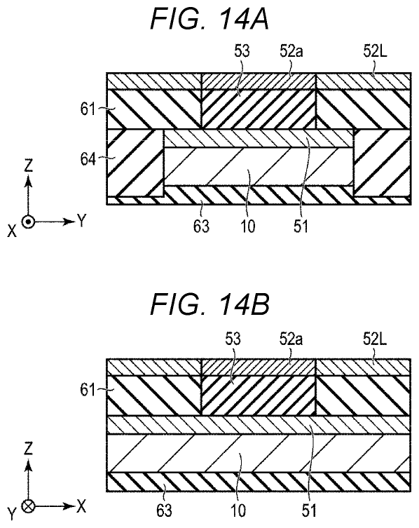

Next, as illustrated in FIGS. 14A and 14B, the patterned resist 73 is removed. By doing so, the selector material layer 53 and the first part 52a of the upper electrode are obtained. The selector material layer 53 is formed between the lower electrode 51 and the first part 52a of the upper electrode, and the shape of the selector material layer 53 and the shape of the first part 52a of the upper electrode 52 correspond to each other (coincide with each other) when viewed from the Z direction.

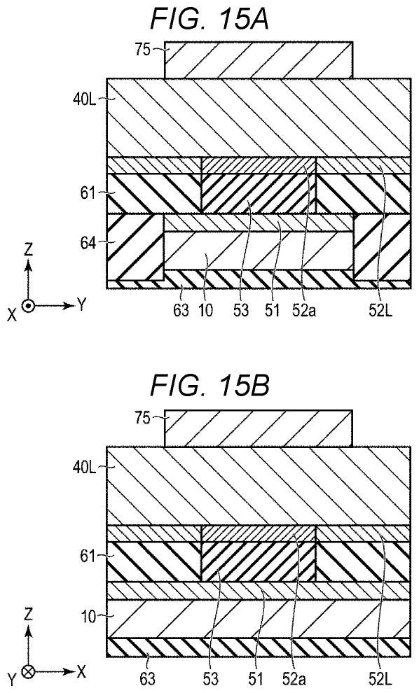

Next, as illustrated in FIGS. 15A and 15B, a magnetoresistive effect element layer 40L is formed on the structure obtained in the steps in FIGS. 14A and 14B. Next, a mask layer is formed on the magnetoresistive effect element layer 40L. Furthermore, a mask 75 is formed by patterning the mask layer. The mask 75 has a circular shape when viewed from the Z direction.

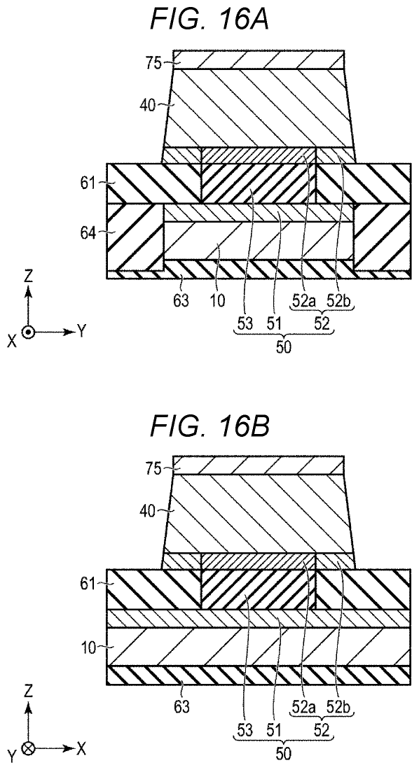

Next, as illustrated in FIGS. 16A and 16B, the magnetoresistive effect element layer 40L and the upper electrode layer 52L are etched through ion beam etching (IBE) using the mask 75 as a mask. Accordingly, the magnetoresistive effect element 40 and the upper electrode 52 are obtained. The upper electrode 52 has the first part 52a and the second part 52b.

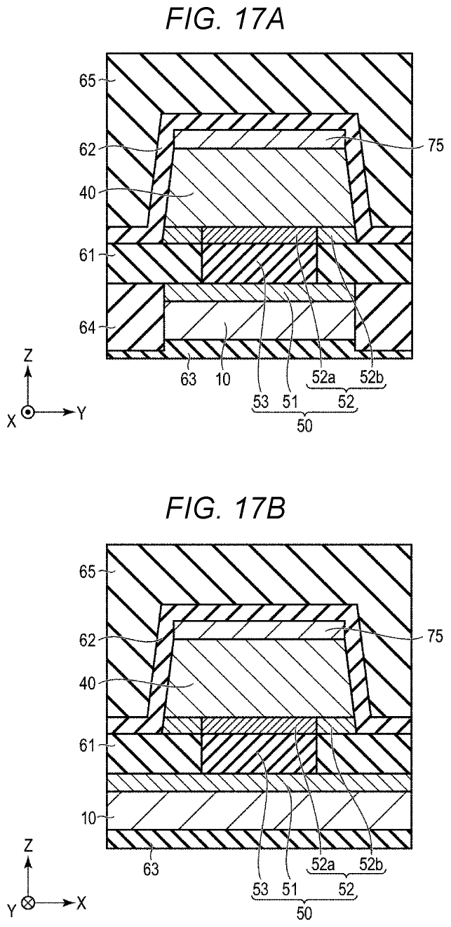

Next, as illustrated in FIGS. 17A and 17B, the insulating layer (e.g., a silicon nitride layer or a silicon oxide layer) 62 is formed on the structure obtained in the steps in FIGS. 16A and 16B, and the insulating layer (e.g., silicon oxide layer) 65 is formed on the insulating layer 62.

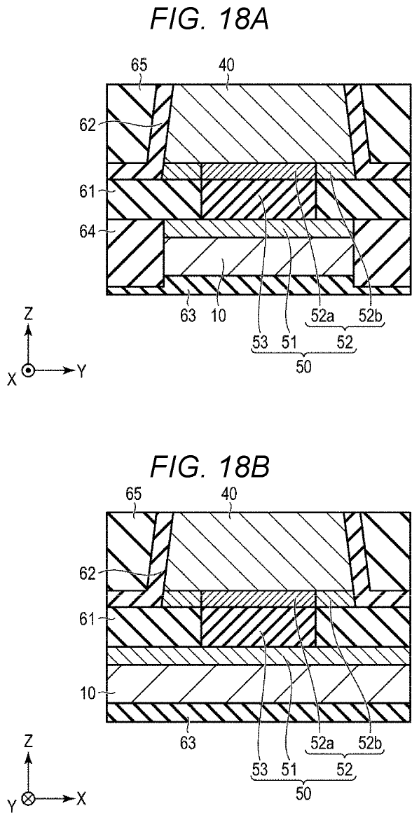

Next, as illustrated in FIGS. 18A and 18B, a flattening process is performed through chemical mechanical etching (CMP), IBE, or the like. Accordingly, an upper surface of the magnetoresistive effect element 40 is exposed.

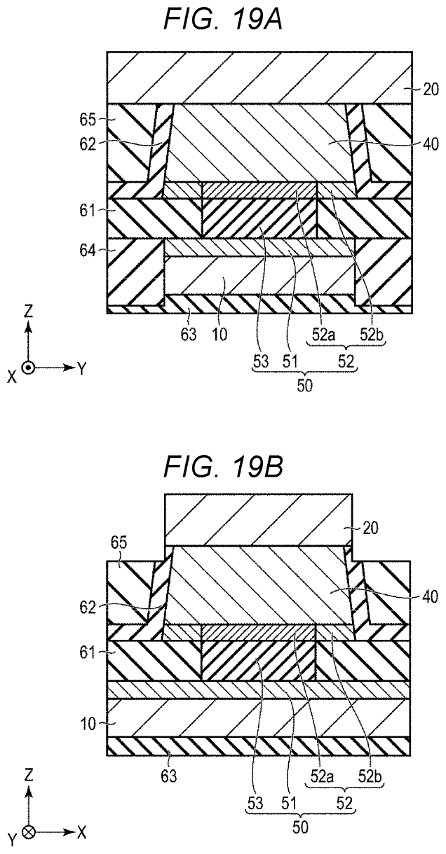

Next, as illustrated in FIGS. 19A and 19B, the wire 20 extending in the Y direction is formed by forming a conductive layer for wires and then patterning the conductive layer.

Then, the insulating layer (e.g., silicon oxide layer) 66 is formed, so that the structure illustrated in FIGS. 3A and 3B is achieved.

As described above, in the present embodiment, the selector material layer 53 is formed by introducing the additive element into the part of the insulating layer 61 through the upper electrode layer 52L in the steps in FIGS. 13A and 13B. Thus, the selector material layer 53 does not need to be formed through etching. In addition, when the magnetoresistive effect element layer 40L and the upper electrode layer 52L are formed in the steps depicted in FIGS. 16A and 16B, side surfaces of the selector material layer 53 are surrounded by the insulating layer 61. Thus, as will be described below, a storage device having an excellent characteristic and excellent reliability can be obtained in the present embodiment.

By contrast, when the selector material layer 53 is formed through etching, the selector material layer 53 may be damaged because of the etching. In addition, an etching product generated in forming the selector material layer 53 may be redeposited on the side surfaces of the magnetoresistive effect element 40 to cause an electrical short failure.

In the present embodiment, the above issues can be effectively avoided, and a storage device having an excellent characteristic and excellent reliability can be obtained.

In addition, in the present embodiment, when the selector material layer 53 is formed by introducing the additive element into the part of the insulating layer 61, the additive element is also introduced into the upper electrode layer 52L to form the first part 52a of the upper electrode 52. However, even when the additive element is introduced into the first part 52a of the upper electrode 52, conductivity of the first part 52a is not affected. Thus, a characteristic of the selector 50 is not adversely affected.

In addition, in the present embodiment, the outer periphery of the selector material layer 53 is overlapped by the magnetoresistive effect element 40 and the upper electrode 52 when viewed from the Z direction. That is, a cross-sectional area of the selector material layer 53 in the Z plane is smaller than that of the magnetoresistive effect element 40 and that of the upper electrode 52. Because of the smaller area, the resistance (in particular, resistance in the Z direction) of the selector 50 can be increased. Consequently, the increase in the resistance of the selector 50 in the off state can reduce a leakage current (also known as off current) when the selector 50 is in the off state. Particularly, since a voltage having a certain magnitude is applied to the selector 50 provided in the half-selected memory cell 30, a higher leakage current (an off current or a half-selection current) flows in the half-selected memory cell 30 than in the non-selected memory cell 30. In the present embodiment, because of the smaller area, the resistance (in particular, resistance in the Z direction) of the selector 50 can be increased, and the leakage current (the off current or the half-selection current) of, particularly, the half-selected memory cell 30 can be effectively reduced.

In addition, in the present embodiment, the wire 10 and the lower electrode 51 having the same planar shape are formed together in the steps in FIGS. 6A and 6B. That is, the pattern of the wire 10 and the pattern of the lower electrode 51 substantially match when viewed from the Z direction. When the wire 10 and the lower electrode 51 are formed in separate steps, a breakdown voltage failure may occur because of variations in alignment. That is, a distance between the lower electrode 51 provided in a first memory cell and the wire 10 connected to a second memory cell is decreased, and a breakdown voltage failure may occur between the first and second memory cells adjacent to each other.

In the present embodiment, since the layout of the wire 10 and the layout of the lower electrode 51 substantially match when viewed from the Z direction, the above issues can be avoided.

### Second Embodiment

Next, a storage device according to a second embodiment, which is non-volatile, will be described. Contents are basically the same as the contents of the first embodiment, and the contents described in the first embodiment will not be described.

FIG. 20 is a perspective view schematically illustrating a schematic basic configuration of the storage device according to the second embodiment.

As in the first embodiment, the storage device of the present embodiment also includes the plurality of wires 10, the plurality of wires 20, and the plurality of memory cells 30 provided between the plurality of wires 10 and the plurality of wires 20.

In addition, even in the present embodiment, the memory cell 30 includes the magnetoresistive effect element 40 and the selector 50 connected in series to the magnetoresistive effect element 40 and has the structure in which the magnetoresistive effect element 40 and the selector 50 are stacked in the Z direction, as in the first embodiment. It is noted that, in the present embodiment, the magnetoresistive effect element 40 is provided on a lower layer side of the selector 50.

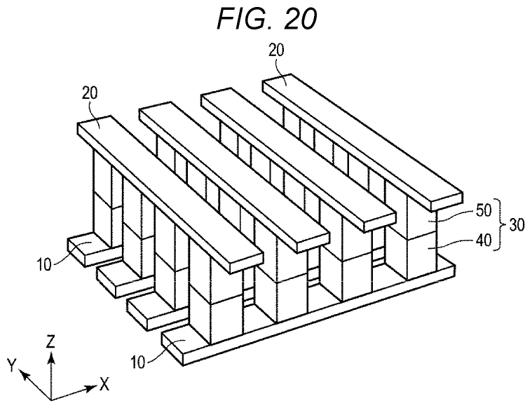

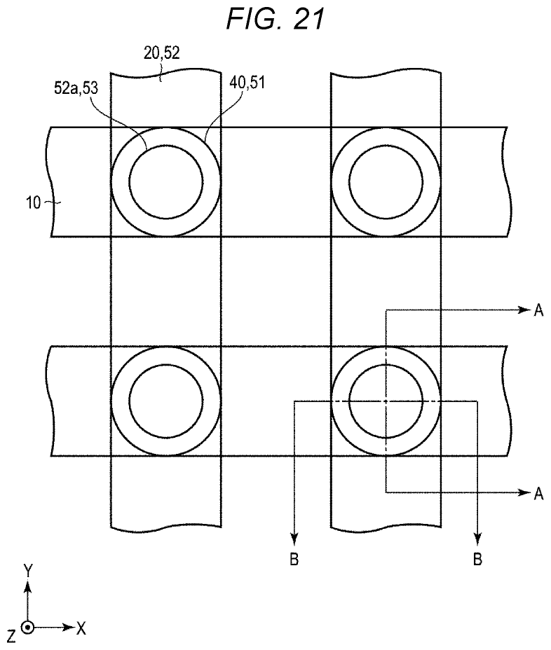

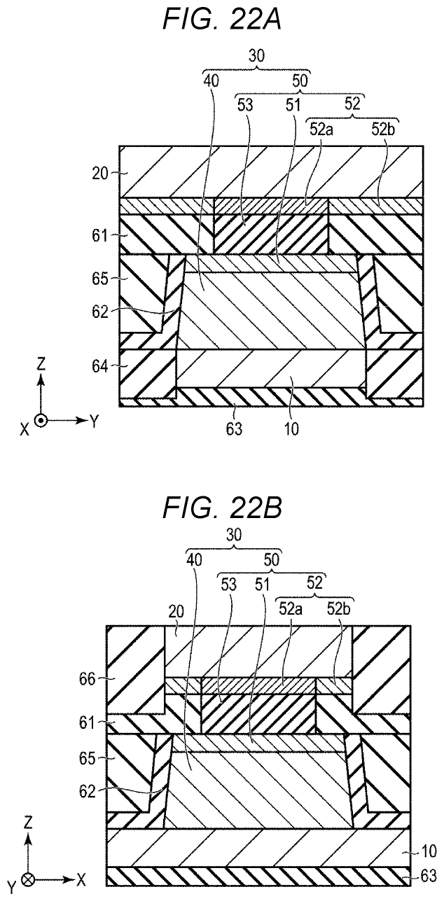

FIG. 21 is a plan view schematically illustrating a configuration of the storage device according to the present embodiment. FIGS. 22A and 22B are cross-sectional views schematically illustrating the configuration of the storage device according to the present embodiment. A cross section taken along line A-A in FIG. 21 corresponds to FIG. 22A, and a cross section taken along line B-B in FIG. 21 corresponds to FIG. 22B.

As illustrated in FIGS. 21, 22A, and 22B, even in the present embodiment, the storage device includes the wire 10, the wire 20, the memory cell 30 including the magnetoresistive effect element 40 and the selector 50, and the insulating layers 61 to 66, as in the first embodiment. It is noted that, as described above, in the present embodiment, the magnetoresistive effect element 40 is provided on the lower layer side of the selector 50.

A basic configuration of the magnetoresistive effect element 40 is the same as the configuration of the magnetoresistive effect element 40 described in the first embodiment.

A basic configuration of the selector 50 is also the same as the configuration of the selector 50 described in the first embodiment and includes the lower electrode 51, the upper electrode 52, and the selector material layer 53.

In the present embodiment, the selector 50 is provided on an upper layer side of the magnetoresistive effect element 40. Thus, the lower electrode 51 also functions as an upper electrode of the magnetoresistive effect element 40. In addition, the shape of the lower electrode 51 corresponds to the shape of the magnetoresistive effect element 40 when viewed from the Z direction. That is, when viewed from the Z direction, the shape of the lower electrode 51 coincides with the shape of the magnetoresistive effect element 40, and the shape of the lower electrode 51 is substantially the same as the shape of the magnetoresistive effect element 40.

The upper electrode 52 is connected to the wire 20, and the layout of the upper electrode 52 follows a layout of the wire 20 when viewed from the Z direction. That is, when viewed from the Z direction, the layout of the upper electrode 52 coincides with the layout of the wire 20, and the layout of the upper electrode 52 is substantially the same as the layout of the wire 20.

As in the first embodiment, the upper electrode 52 has the first part 52a and the second part 52b. The first part 52a and the second part 52b are contiguously provided and have the same thickness.

The first part 52a and the second part 52b have basically the same configurations as the first part 52a and the second part 52b of the first embodiment. That is, the first part 52a is formed of a conductive material to which an additive element is added. The conductive material and the additive element are the same as the conductive material and the additive element of the first embodiment. The second part 52b is formed of the conductive material to which the additive element is not added. In addition, the second part 52b surrounds the first part 52a and is positioned outside the first part 52a when viewed from the Z direction.

As in the first embodiment, the selector material layer 53 is provided between the lower electrode 51 and the upper electrode 52. The outer periphery of the selector material layer 53 is overlapped by the lower electrode 51 and the upper electrode 52 when viewed from the Z direction. More specifically, the selector material layer 53 is provided between the lower electrode 51 and the first part 52a of the upper electrode 52, and the shape of the first part 52a of the upper electrode 52 corresponds to the shape of the selector material layer 53 when viewed from the Z direction. That is, when viewed from the Z direction, the shape of the first part 52a of the upper electrode 52 coincides with the shape of the selector material layer 53, and the shape of the first part 52a of the upper electrode 52 substantially matches the shape of the selector material layer 53. In addition, the outer periphery of the selector material layer 53 is overlapped by the magnetoresistive effect element 40 when viewed from the Z direction.

In addition, as in the first embodiment, the selector material layer 53 is formed of an insulating material to which the additive element is added. A specific insulating material is the same as the insulating material described in the first embodiment.

As in the first embodiment, the insulating layer (first insulating layer) 61 surrounds the selector material layer 53 and is positioned outside the selector material layer 53 when viewed from the Z direction. The insulating layer 61 and the selector material layer 53 are contiguously provided and have the same thickness. The insulating layer 61 is formed of an insulating material to which the additive element is not added. The insulating material of the insulating layer 61 is the same as the insulating material described in the first embodiment.

The insulating layers 62, 63, 64, 65, and 66 are substantially the same as the insulating layers 62, 63, 64, 65, and 66 described in the first embodiment.

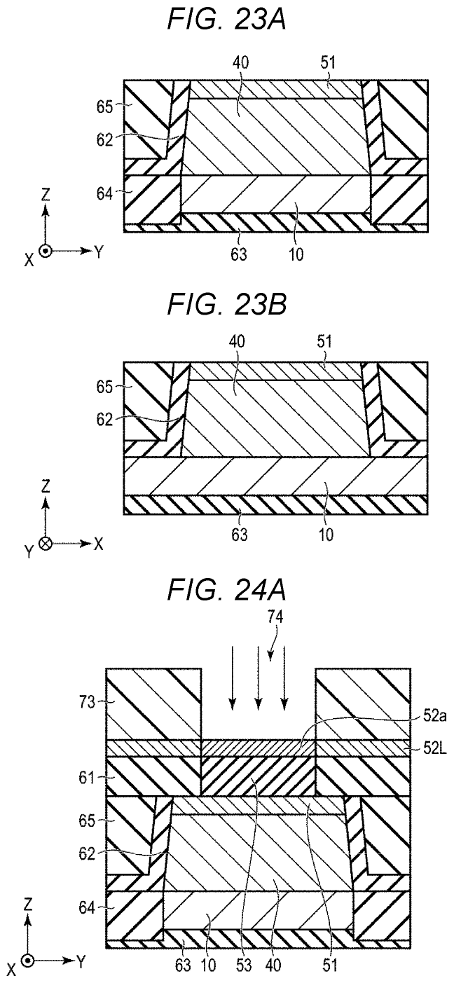

Next, a method of manufacturing the storage device according to the present embodiment will be described with reference to the cross-sectional views illustrated in FIGS. 23A to 25A and the cross-sectional views illustrated in FIGS. 23B to 25B.

First, steps in FIGS. 23A and 23B are performed. Specifically, first, a structure including the wire 10, the insulating layer 63, and the insulating layer 64 is formed. Next, a magnetoresistive effect element layer and a lower electrode layer are formed, and the magnetoresistive effect element layer and the lower electrode layer are patterned together. Accordingly, the magnetoresistive effect element 40 and the lower electrode 51 are formed. Furthermore, the insulating layer 62 and the insulating layer 65 are formed.

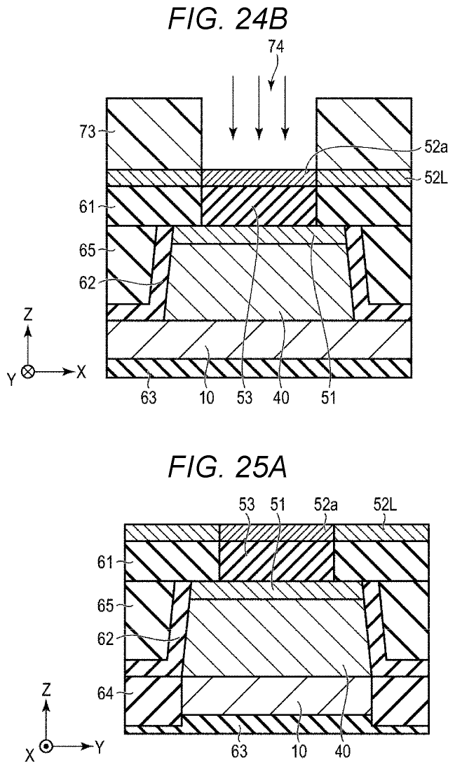

Next, steps in FIGS. 24A and 24B are performed. Specifically, first, the insulating layer 61 is formed on the structure obtained in the steps in FIGS. 23A and 23B, and the upper electrode layer 52L is formed on the insulating layer 61. Next, the patterned resist 73 having the hole pattern 74 is formed on the upper electrode layer 52L. The patterned resist 73 having the hole pattern 74 is formed using the same method as in the first embodiment. Next, as in the first embodiment, ions of the additive element are implanted using the patterned resist 73 as a mask. Accordingly, as in the first embodiment, the selector material layer 53 and the first part 52a of the upper electrode 52 (which is formed in a step described later) are formed.

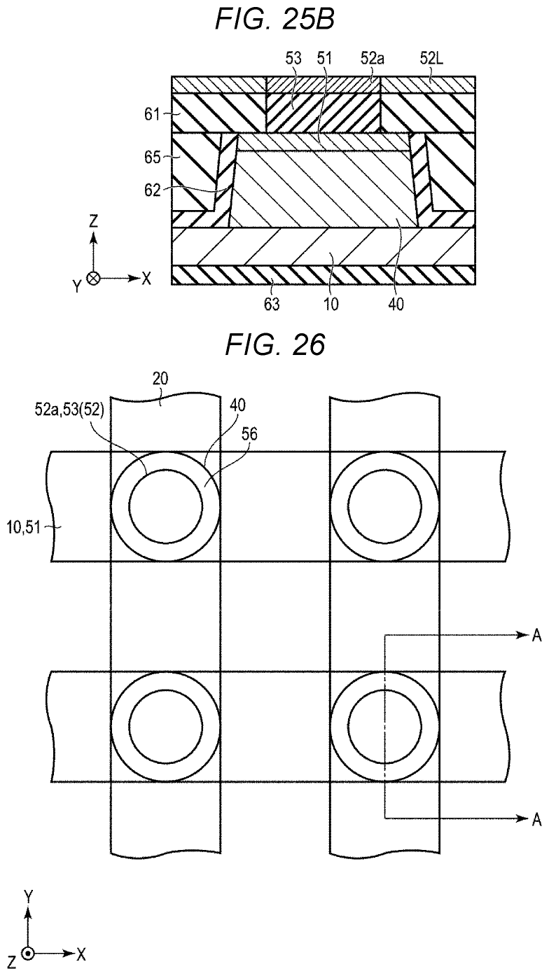

Next, as illustrated in FIGS. 25A and 25B, the patterned resist 73 is removed. By doing so, the selector material layer 53 and the first part 52a of the upper electrode are obtained. The selector material layer 53 is formed between the lower electrode 51 and the first part 52a of the upper electrode, and the shape of the selector material layer 53 and the shape of the first part 52a of the upper electrode 52 correspond to each other (coincide with each other) when viewed from the Z direction.

Then, as illustrated in FIGS. 22A and 22B, a conductive layer for wires is formed, and then the conductive layer and the upper electrode layer 52L are patterned together. Accordingly, the wire 20 extending in the Y direction and the upper electrode 52 are formed. Furthermore, the insulating layer 66 is formed, so that the structure illustrated in FIGS. 22A and 22B is achieved.

As described above, even in the present embodiment, the selector material layer 53 and the first part 52a of the upper electrode are formed, as in the first embodiment. Accordingly, even in the present embodiment, the same effect as the first embodiment can be obtained.

In addition, in the present embodiment, the wire 20 and the upper electrode 52 having the same planar shape are formed together. That is, the layout of the wire 20 and the layout of the upper electrode 52 substantially match when viewed from the Z direction. When the wire 20 and the upper electrode 52 are formed in separate steps, a breakdown voltage failure may occur because of variations in alignment. That is, a distance between the upper electrode 52 provided in the first memory cell and the wire 20 connected to the second memory cell is decreased, and a breakdown voltage failure may occur between the first and second memory cells adjacent to each other.

In the present embodiment, since the layout of the wire 20 and the layout of the upper electrode 52 substantially match when viewed from the Z direction, the above issues can be avoided.

### Third Embodiment

Next, a storage device according to a third embodiment will be described. Contents are basically the same as the contents of the first embodiment, and the contents described in the first embodiment will not be described.

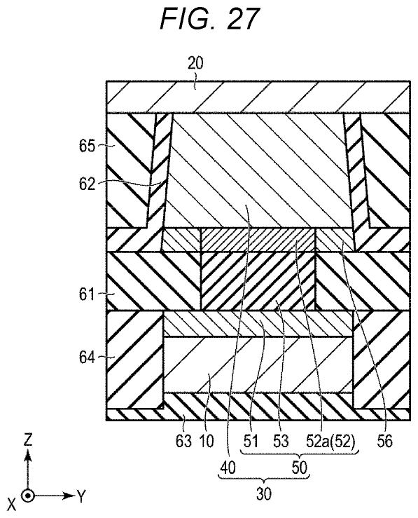

FIG. 26 is a plan view schematically illustrating a configuration of the storage device according to the present embodiment. FIG. 27 is a cross-sectional view schematically illustrating the configuration of the storage device according to the present embodiment. A cross section taken along line A-A in FIG. 26 corresponds to FIG. 27.

While the upper electrode 52 has the first part 52a and the second part 52b in the first embodiment, the upper electrode 52 is substantially formed with only the first part 52a and does not have the second part 52b in the present embodiment. In the present embodiment, a semiconductor part 56 is provided at a position corresponding to the second part 52b.

In the present embodiment, the first part 52a of the upper electrode 52 is formed of a semiconductor material to which an additive element is added, and the semiconductor part 56 is formed of the semiconductor material to which the additive element is not added. That is, the semiconductor part 56 and the first part 52a of the upper electrode 52 have the same semiconductor material. For example, silicon (Si) is used as the semiconductor material. The additive element described in the first embodiment may be used as the additive element.

As in the first embodiment, in forming the selector material layer 53 by introducing the additive element into the insulating layer 61, the additive element is also introduced into a semiconductor layer of the first part 52a for the upper electrode 52 to form the first part 52a of the upper electrode 52.

The semiconductor part 56 is formed of an intrinsic semiconductor and has very high resistance, compared to the first part 52a of the upper electrode 52. Thus, in the present embodiment, the first part 52a substantially functions as the upper electrode 52, and the first part 52a substantially matches the upper electrode 52.

A method of manufacturing according to the present embodiment is basically the same as the method of manufacturing according to the first embodiment. The selector material layer 53 and the first part 52a of the upper electrode are formed in the same manner as the first embodiment. Accordingly, even in the present embodiment, the same effect as the first embodiment can be obtained.

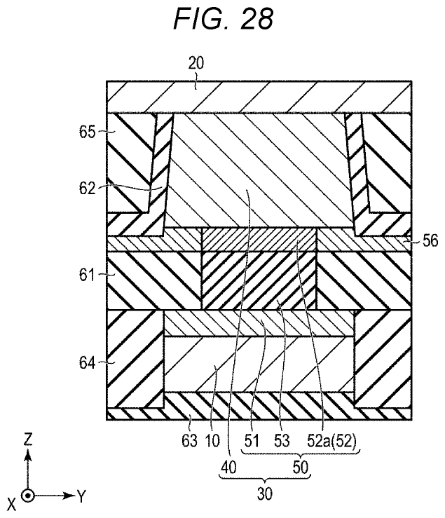

FIG. 28 is a cross-sectional view schematically illustrating a configuration of a storage device according to a first modification example of the present embodiment.

Even in the present modification example, the first part 52a of the upper electrode 52 is formed of a semiconductor material to which an additive element is added, the semiconductor part 56 is formed of the semiconductor material to which the additive element is not added, and the selector material layer 53 is formed of an insulating material to which the additive element is added, as in the third embodiment.

However, in the third embodiment, the semiconductor part 56 is formed by completely removing the semiconductor layer outside the outer periphery of the magnetoresistive effect element 40 when viewed from the Z direction, when the pattern of the magnetoresistive effect element 40 is formed. Accordingly, the semiconductor part 56 is not provided outside the outer periphery of the magnetoresistive effect element 40 when viewed from the Z direction.

In the present modification example, the semiconductor part 56 is formed by leaving a part of the semiconductor layer outside the outer periphery of the magnetoresistive effect element 40 when viewed from the Z direction, when the magnetoresistive effect element 40 is formed. Accordingly, in the present modification example, the semiconductor part 56 overlaps the outer periphery of the magnetoresistive effect element 40 when viewed from the Z direction.

A method of manufacturing according to the present modification example is also basically the same as the method of manufacturing according to the first embodiment. The selector material layer 53 and the first part 52a of the upper electrode are formed in the same manner as the first embodiment. Accordingly, even in the present modification example, the same effect as the first embodiment can be obtained.

In the present modification example, since the semiconductor part 56 overlaps the outer periphery of the magnetoresistive effect element 40, the semiconductor part 56 is present in a region between adjacent upper electrodes 52 (first parts 52a) between adjacent memory cells. However, since resistance of the semiconductor part 56 is very high, insulation between the adjacent upper electrodes 52 can be achieved.

FIG. 29 is a cross-sectional view schematically illustrating a configuration of a storage device according to a second modification example of the present embodiment.

In the first modification example, the semiconductor part 56 is formed by leaving a part of the semiconductor layer outside the outer periphery of the magnetoresistive effect element 40 when viewed from the Z direction, when the pattern of the magnetoresistive effect element 40 is formed. In the present modification example, an insulating part 57 is formed by performing an insulating process on a part of the semiconductor layer outside the outer periphery of the magnetoresistive effect element 40 when viewed from the Z direction. Specifically, the insulating part 57 is formed by oxidizing the semiconductor layer using oxygen plasma. Accordingly, in the present modification example, the insulating part 57 is provided outside the outer periphery of the magnetoresistive effect element 40 when viewed from the Z direction.

A method of manufacturing according to the present modification example is also basically the same as the method of manufacturing according to the first embodiment. The selector material layer 53 and the first part 52a of the upper electrode are formed in the same manner as the first embodiment. Accordingly, even in the present modification example, the same effect as the first embodiment can be obtained.

In addition, in the present modification example, since the insulating part 57 is provided outside the outer periphery of the magnetoresistive effect element 40 when viewed from the Z direction, insulation between the adjacent upper electrodes 52 (first parts 52a) can be more securely achieved, compared to the insulation in the first modification example.

### Fourth Embodiment

Next, a storage device according to a fourth embodiment will be described. Contents are basically the same as the contents of the first embodiment, and the contents described in the first embodiment will not be described.

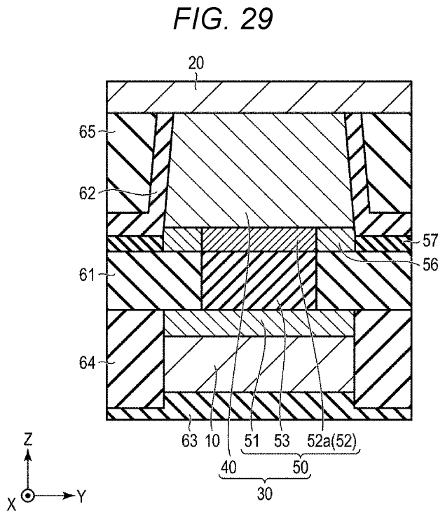

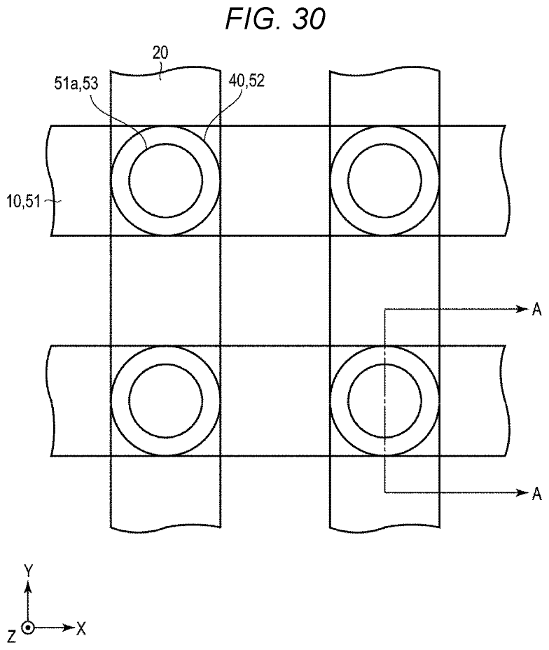

FIG. 30 is a plan view schematically illustrating a configuration of the storage device according to the present embodiment. FIG. 31 is a cross-sectional view schematically illustrating the configuration of the storage device according to the present embodiment. A cross section taken along line A-A in FIG. 30 corresponds to FIG. 31.

While the first part 52a is provided in the upper electrode 52 of the selector 50 in the first to third embodiments, a first part 51a is provided in the lower electrode 51 of the selector 50 in the present embodiment. That is, in the present embodiment, the lower electrode 51 has the first part 51a and a second part 51b. The first part 51a and the second part 51b are contiguously provided and have the same thickness.

The first part 51a is formed of a conductive material to which an additive element is added. The additive element and the conductive material described in the first embodiment are used as the additive element and the conductive material.

The second part 51b surrounds the first part 51a and is positioned outside the first part 51a when viewed from the Z direction. The second part 51b is formed of the conductive material to which the additive element is not added. That is, the first part 51a and the second part 51b have the same conductive material, the additive element is added to the first part 51a, and the additive element is not added to the second part 51b.

In the present embodiment, the selector material layer 53 is provided between the first part 51a of the lower electrode 51 and the upper electrode 52, and a shape of the first part 51a of the lower electrode 51 corresponds to the shape of the selector material layer 53 when viewed from the Z direction. That is, when viewed from the Z direction, the shape of the first part 51a of the lower electrode 51 coincides with the shape of the selector material layer 53, and the shape of the first part 51a of the lower electrode 51 substantially matches the shape of the selector material layer 53.

The selector material layer 53 is formed of an insulating material to which the additive element is added. That is, the selector material layer 53 is formed of an insulating material to which the same additive element as the additive element contained in the first part 51a of the lower electrode 51 is added. A specific insulating material is the same as the insulating material described in the first embodiment.

The selector material layer 53 is provided between the lower electrode 51 and the upper electrode 52. The outer periphery of the selector material layer 53 is overlapped by the lower electrode 51 and the upper electrode 52 when viewed from the Z direction. More specifically, the selector material layer 53 is provided between the first part 51a of the lower electrode 51 and the upper electrode 52, and the shape of the first part 51a of the lower electrode 51 corresponds to the shape of the selector material layer 53 when viewed from the Z direction. That is, when viewed from the Z direction, the shape of the first part 51a of the lower electrode 51 coincides with the shape of the selector material layer 53, and the shape of the first part 51a of the lower electrode 51 substantially matches the shape of the selector material layer 53. In addition, the outer periphery of the selector material layer 53 is overlapped by the magnetoresistive effect element 40 when viewed from the Z direction.

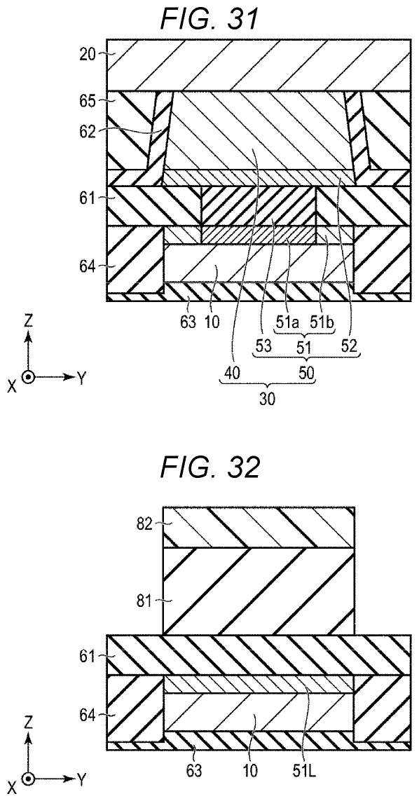

Next, a method of manufacturing the storage device according to the present embodiment will be described with reference to the cross-sectional views illustrated in FIGS. 32 to 34.

First, a step in FIG. 32 is performed. Specifically, first, a structure including the wire 10, the lower electrode layer 51L, the insulating layer 61, the insulating layer 63, and the insulating layer 64 is formed. Next, a material layer using a material having high etching selectivity for the insulating layer 61 is formed on the insulating layer 61. Furthermore, a material layer pattern 81 is formed by etching the material layer using a patterned resist 82 as a mask.

Next, as illustrated in FIG. 33, a material layer pattern 81s is formed by shrinking the material layer pattern 81.

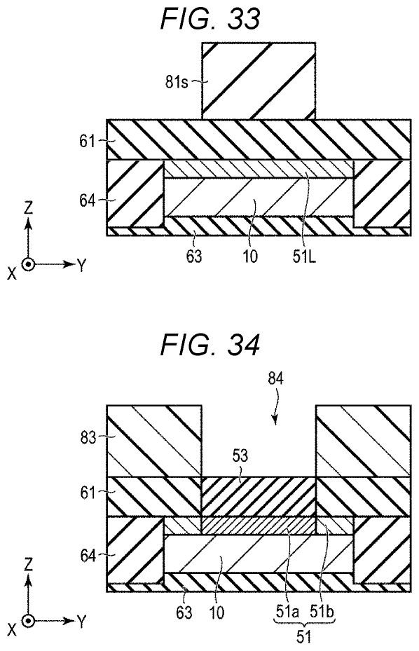

Next, as illustrated in FIG. 34, the patterned resist 83 surrounding the material layer pattern 81s is formed, and then the material layer pattern 81s is removed. Accordingly, the patterned resist 83 having a hole pattern 84 is obtained. Next, ions of the additive element are implanted into a part of the insulating layer 61 using the patterned resist 83 as a mask. By implanting the ions, the additive element is introduced into the part of the insulating layer 61 to form the selector material layer 53. In the ion implantation step, the additive element is also introduced into a part of the lower electrode layer 51L through the part of the insulating layer 61 to form the first part 51a of the lower electrode 51. In addition, the part of the lower electrode layer 51L to which the additive element is not introduced becomes the second part 51b surrounding the first part 51a.

After the patterned resist 83 is removed, the upper electrode 52, the magnetoresistive effect element 40, the insulating layer 62, the insulating layer 65, and the wire 20 are formed, so that the structure illustrated in FIG. 31 is achieved.

As described above, in the present embodiment, the selector material layer 53 is formed by introducing the additive element into the part of the insulating layer 61 in the step in FIG. 34. Accordingly, even in the present embodiment, the same effect as the first embodiment can be obtained.

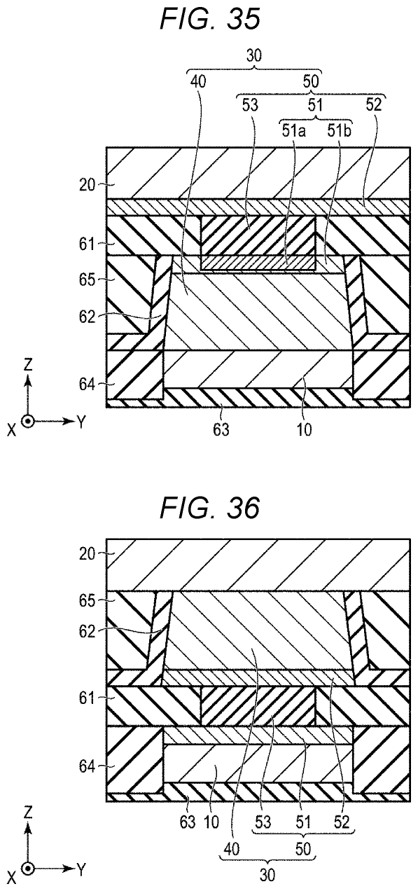

FIG. 35 is a cross-sectional view schematically illustrating a configuration of a storage device according to a first modification example of the present embodiment.

While the selector 50 is provided on the lower layer side of the magnetoresistive effect element 40 in the embodiment, the selector 50 is provided on the upper layer side of the magnetoresistive effect element 40 in the present modification example. In addition, in the present modification example, a part of the second part 51b is also provided below the first part 51a of the lower electrode 51.

Even in the present modification example, the selector material layer 53 is formed by introducing the additive element into the part of the insulating layer 61. Accordingly, even in the present modification example, the same effect as the embodiment can be obtained.

FIG. 36 is a cross-sectional view schematically illustrating a configuration of a storage device according to a second modification example of the present embodiment.

In the fourth embodiment, in introducing the additive element into the insulating layer 61, the additive element is also introduced into the lower electrode layer 51L to form the first part 51a of the lower electrode 51. Alternatively, the additive element may not be introduced into the lower electrode layer 51L in introducing the additive element into the insulating layer 61. In this case, a structure in which the additive element is not added to the entire lower electrode 51 is obtained.

Even in the present modification example, the selector material layer 53 is formed by introducing the additive element into the part of the insulating layer 61. Accordingly, even in the present modification example, the same effect as the embodiment can be obtained.

In the fourth embodiment, the first part 51a may be provided in the entire lower electrode 51 in a thickness direction (Z direction), or the first part 51a may be provided in a part of the lower electrode 51 in the thickness direction. That is, the second part 51b may be provided below the first part 51a, as in the first modification example.

In addition, when the first part 52a is provided in the upper electrode 52 as in the first to third embodiments, the first part 52a may be provided in the entire upper electrode 52 in the thickness direction, or the first part 52a may be provided in a part of the upper electrode 52 in the thickness direction. That is, the second part 52b may be provided above the first part 52a.

In addition, in the second modification example of the fourth embodiment, the additive element is not introduced into the lower electrode layer 51L so that the first part 51a is not provided in the lower electrode 51. Even in the first to third embodiments, the additive element may also not be introduced into the upper electrode layer 52L so that the first part 52a is not provided in the upper electrode 52.

In addition, while the magnetoresistive effect element is used as the variable resistance storage element in the first to fourth embodiments, a variable resistance storage element other than the magnetoresistive effect element may be used.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A storage device comprising:
a memory cell that includes a variable resistance storage element and a switching element connected in series to the variable resistance storage element and stacked with the variable resistance storage element in a first direction,
the switching element including a first electrode, a second electrode that includes a first part formed of a first material to which a first element is added, and a switching material layer that is provided between the first electrode and the first part of the second electrode and that is formed of a first insulating material to which the first element is added; and
a first insulating layer that surrounds the switching material layer and is formed of the first insulating material to which the first element is not added,
wherein an outer periphery of the first part of the second electrode and an outer periphery of the switching material layer are aligned in the first direction.

2. The storage device according to claim 1,
wherein the second electrode further includes a second part that surrounds the first part and does not overlap the switching material in the first direction.

3. The storage device according to claim 1,
wherein an outer periphery of the switching material layer and an outer periphery of the variable resistance storage element are not aligned in the first direction.

4. The storage device according to claim 1,
wherein the second electrode further includes a second part that surrounds the first part when viewed from the first direction and that is formed of the first material to which the first element is not added.

5. The storage device according to claim 1,
wherein the first element is a metal element.

6. The storage device according to claim 1,
wherein the first element is one of arsenic (As), bismuth (Bi), tellurium (Te), and germanium (Ge).

7. The storage device according to claim 1,
wherein the first insulating material is an oxide or a nitride.

8. The storage device according to claim 1,
wherein the first insulating material is one of a silicon oxide, a zirconium oxide, an aluminum oxide, a silicon nitride, and a hafnium oxide.

9. The storage device according to claim 1,
wherein the first material is a conductive material or a semiconductor material.

10. The storage device according to claim 1,
wherein the first material is one of a titanium nitride, silicon, aluminum, tantalum, tungsten, a tungsten nitride, copper, and carbon.

11. The storage device according to claim 1, further comprising:
a wire connected to the first electrode,
wherein a layout of the first electrode substantially matches a layout of the wire when viewed from the first direction.

12. The storage device according to claim 1, further comprising:
a wire connected to the second electrode,
wherein a layout of the second electrode substantially matches a layout of the wire when viewed from the first direction.

13. The storage device according to claim 1,
wherein the variable resistance storage element is a magnetoresistive effect element.

14. A method of manufacturing a storage device including a memory cell that includes a variable resistance storage element and a switching element connected in series to the variable resistance storage element and stacked with the variable resistance storage element,
the switching element including a first electrode, a second electrode, and a switching material layer that is provided between the first electrode and the second electrode and that is formed of a first insulating material to which a first element is added,
the method comprising:
introducing the first element into a part of a first insulating layer formed of the first insulating material to which the first element has not been added, to form the switching material layer.

15. The method according to claim 14, further comprising:
introducing the first element into a first part of a layer for the second electrode, wherein
the switching material layer is between the first electrode and the first part of the layer for the second electrode.

16. The method according to claim 15, wherein
the first element is introduced into the part of the first insulating layer through the first part of the layer for the second electrode.

17. The method according to claim 16, wherein the storage device further includes a wire connected to the first electrode, and a layout of the wire substantially matches a layout of the first electrode when viewed from a direction along which the variable resistance storage element and the switching element are stacked.

18. The method according to claim 16, wherein the storage device further includes a wire connected to the second electrode, and a layout of the wire substantially matches a layout of the second electrode when viewed from a direction along which the variable resistance storage element and the switching element are stacked.

19. The method according to claim 15, wherein
the first element is introduced into the first part of the layer for the second electrode through the part of the first insulating layer.

20. The method according to claim 19, wherein the first electrode is between the variable resistance storage element and the switching material layer.
